(19) United States
(12) Patent Application Publication
(10) Pub. No.: US 2016/0071751 A1
(43) Pub. Date: Mar. 10, 2016

(54) SHEET ATTACHMENT DEVICE AND ATTACHMENT METHOD

(71) Applicant: LINTEC CORPORATION, Tokyo (JP)

(72) Inventors: Kouji OKAMOTO, Tokyo (JP); Kenichi WATANABE, Tokyo (JP)

(21) Appl. No.: 14/786,156

(22) PCT Filed: Apr. 11, 2014
(86) PCT No.: PCT/JP2014/060451

§ 371 Date: Oct. 21, 2015

(30) Foreign Application Priority Data
Apr. 26, 2013 (JP) 2013-094164

(51) Int. Cl. H01L 21/67

(52) U.S. Cl. CPC H01L 21/67132; H01L 21/67282; H01L 21/67259

(57) ABSTRACT

A sheet sticking apparatus includes: a feeder configured to feed an adhesive sheet; a press unit configured to press and stick the adhesive sheet to an adherend provided with a reference portion at a predetermined position; and a mark-providing unit configured to provide a predetermined position recognition mark to the adhesive sheet at a predetermined position within an area stuck to the adherend, the position recognition mark having a predetermined positional pattern relative to the reference portion.

### TECHNICAL FIELD

The present invention relates to a sheet sticking apparatus and a sheet sticking method for sticking an adhesive sheet to an adherend.

### BACKGROUND ART

A typical sheet sticking apparatus used to stick an adhesive sheet to a semiconductor wafer (hereinafter, occasionally simply referred to as “wafer”) during a semiconductor manufacturing process has been known (see, for instance, Patent Literature 1).

The sheet sticking apparatus of Patent Literature 1 includes: a sheet-feeding unit that feeds an adhesive sheet in a manner that the adhesive sheet faces a wafer (adhesive) with an outer periphery provided with a notch (reference portion); a fine-cutting unit that provides a cut to the adhesive sheet; and a press roller that presses and sticks the adhesive sheet to the wafer with the cut of the adhesive sheet being positioned relative to the notch of the wafer.

### CITATION LIST

### Patent Literature(s)

Patent Literature 1: JP-A-2007-307655

### SUMMARY OF THE INVENTION

### Problem(s) to be Solved by the Invention

After being stuck with the adhesive sheet by the typical sheet sticking apparatus of Patent Literature 1, the adherend is transported to a downstream apparatus (e.g., a grinding apparatus and a cutting apparatus), in which the reference portion is detected by a detector to perform a variety of processes with reference to the position of the reference portion.

However, the typical sheet sticking apparatus entails a problem that the detector of the downstream apparatus misunderstands a crack, damage or the like of the adherend as the reference portion, thereby causing a trouble in the process of the adherend.

Alternatively, the detector of the downstream apparatus may detect the cut of the adhesive sheet stuck by the sheet sticking apparatus of Patent Literature 1. However, even such a method could not completely solve the above problem because the detector may fail to detect the cut when the adhesive sheet is clear or translucent.

An object of the invention is to provide a sheet sticking apparatus and a sheet sticking method that are capable of sticking an adhesive sheet to an adherend in a manner that a reference portion of the adherend is recognizable to a downstream apparatus.

### Means for Solving the Problem(s)

According to an aspect of the invention, a sheet sticking apparatus includes: a feeder configured to feed an adhesive sheet; a press unit configured to press and stick the adhesive sheet to an adherend provided with a reference portion at a predetermined position; and a mark-providing unit configured to provide a predetermined position recognition mark to the adhesive sheet at a predetermined position within an area stuck to the adherend, the position recognition mark having a predetermined positional pattern relative to the reference portion.

In the above aspect, it is preferable that the mark-providing unit causes a chemical reaction of a component of the adhesive sheet to provide the position recognition mark.

According to another aspect of the invention, a sheet sticking method includes: feeding an adhesive sheet; pressing and sticking the adhesive sheet to an adherend provided with a reference portion at a predetermined position; and providing a predetermined position recognition mark to the adhesive sheet at a predetermined position within an area stuck to the adherend, the position recognition mark having a predetermined positional pattern relative to the reference portion.

In the above aspects of the invention, the predetermined position recognition mark, which has the predetermined positional pattern relative to the reference portion, is provided to the adhesive sheet at the predetermined position within the area stuck to the adherend. The adhesive sheet can thus be stuck to the adherend in a manner that a downstream apparatus can recognize the reference portion of the adherend.

Further, when the mark-providing unit provides the position recognition mark by causing a chemical reaction of a component of the adhesive sheet, it is possible to prevent the position recognition mark from being abraded or made to disappear.

### BRIEF DESCRIPTION OF DRAWING(S)

FIG. 1 is a side view showing a sheet sticking apparatus according to an exemplary embodiment of the invention.

FIG. 2A is a plan view showing an adherend stuck with an adhesive sheet provided with a position recognition mark.

FIG. 2B is a plan view showing the adherend stuck with the adhesive sheet provided with the position recognition mark.

FIG. 2C is a plan view showing the adherend stuck with the adhesive sheet provided with the position recognition mark.

FIG. 2D is a plan view showing the adherend stuck with the adhesive sheet provided with the position recognition mark.

FIG. 2E is a plan view showing the adherend stuck with the adhesive sheet provided with the position recognition mark.

FIG. 2F is a plan view showing the adherend stuck with the adhesive sheet provided with the position recognition mark.

FIG. 2G is a plan view showing the adherend stuck with the adhesive sheet provided with the position recognition mark.

FIG. 2H is a plan view showing the adherend stuck with the adhesive sheet provided with the position recognition mark.

FIG. 2I is a plan view showing the adherend stuck with the adhesive sheet provided with the position recognition mark.

FIG. 2J is a plan view showing the adherend stuck with the adhesive sheet provided with the position recognition mark.

### DESCRIPTION OF EMBODIMENT(S)

An exemplary embodiment of the invention will be described below with reference to the attached drawings.

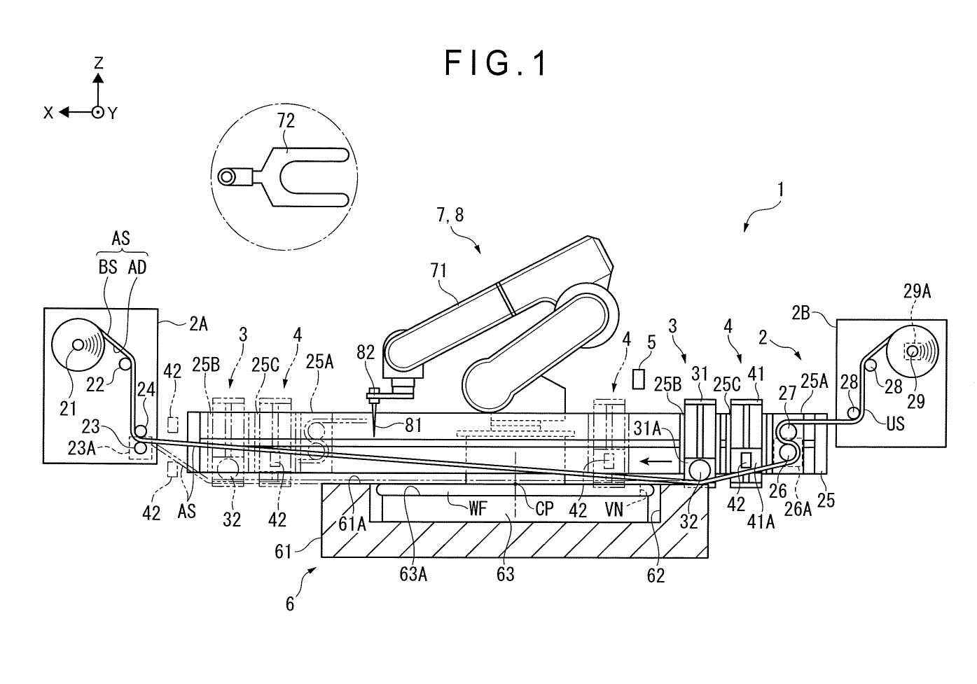

It should be noted that X-, Y- and Z-axes herein are orthogonal to one another, the X- and Y-axes being defined within a horizontal plane, the Z-axis being orthogonal to the horizontal plane. Further, in the exemplary embodiment, a reference state is defined as viewed from a near side in a depth direction parallel with the Y-axis in FIG. 1, a direction of “upper” means a direction indicated by an arrow of the Z-axis and a direction of “lower” means the direction opposite thereto, a direction of “left” means a direction indicated by an arrow of the X-axis and a direction of “right” means the direction opposite thereto, and a direction of “front” means a direction indicated by an arrow of the Y-axis (i.e., the depth direction orthogonal to the plane of paper) and a direction of “rear” means the direction opposite thereto.

As shown in FIG. 1, a sheet sticking apparatus 1 includes: a feeder 2 that feeds a belt-shaped adhesive sheet AS that includes a base sheet BS and an adhesive layer AD provided on a surface of the base sheet BS; a press unit 3 that presses and sticks the adhesive sheet AS to a wafer WF (adherend) provided with a notch VN (reference portion) at a predetermined position (outer periphery); a mark-providing unit 4 that provides a predetermined position recognition mark PM to the adhesive sheet AS at a predetermined position within an area stuck to the wafer WF, the position recognition mark PM having a predetermined positional pattern relative to the notch VN (i.e., being positioned relative to the notch VN according to a predetermined rule); a detector 5 that detects the notch VN; a support unit 6 that supports the wafer WF; a transport unit 7 that transports the wafer WF; and a cutter 8 that cuts the adhesive sheet AS.

The feeder 2 includes: a support roller 21 that supports the adhesive sheet AS; a guide roller 22 that guides the adhesive sheet AS; a pinch roller 24 that faces a drive roller 23 driven by a rotary motor 23A (driver) to hold the adhesive sheet AS therebetween; a drive roller 26 that is rotated by a rotary motor 26A (driver) supported by a slider 25A of a linear motor 25 (driver); a pinch roller 27 that faces the drive roller 26 to hold the adhesive sheet AS therebetween; a plurality of guide rollers 28 that guide an unnecessary sheet US generated by cutting the adhesive sheet AS; and a recycling roller 29 that is driven by a rotary motor 29A (driver) to collect the unnecessary sheet US. The rollers 21 to 24 are supported by a feed-side frame 2A, and the rollers 28, 29 are supported by a recycle-side frame 2B.

The press unit 3 includes: a linear motor 31 (driver) supported by a slider 25B of the linear motor 25; and a press roller 32 supported by a slider 31A of the linear motor 31.

The mark-providing unit 4 includes: a linear motor 41 (driver) supported by a slider 25C of the linear motor 25; and a printer 42 supported by a slider 41A of the linear motor 41.

The detector 5 may be a non-contact sensor (e.g., an optical sensor and an ultrasonic sensor), a contact sensor (e.g., a limit switch) or an image pickup device (e.g., a camera).

The support unit 6 includes: an outer table 61 provided with a recess 62; and an inner table 63 provided in the recess 62 and having a support surface 63A capable of retention by suction in cooperation with a decompressor such as a decompression pump and a vacuum ejector (not shown).

The transport unit 7 includes a multijoint robot 71 (driver); and a suction tool 72 capable of being in communication with the decompressor such as a decompression pump and a vacuum ejector (not shown), the suction tool 72 being removably attachable to a tip end of the multijoint robot 71. The multijoint robot 71 is a so-called six-axial robot capable of moving an object held on its tip end by suction to any position and at any angle within a work area thereof.

The cutter 8 includes: the multijoint robot 71; and a cutter tool 82 including a cutter blade 81, the cutter tool 82 being removably attachable to the tip end of the multijoint robot 71.

Description will be made on a process for sticking the adhesive sheet AS to the wafer WF in the sheet sticking apparatus 1.

The adhesive sheet AS is first set as shown by solid lines in FIG. 1. The transport unit 7 then drives the multijoint robot 71 and the decompressor (not shown) to retain the wafer WF by suction with the suction tool 72 so that the detector 5 detects the outer periphery of the wafer WF and the notch VN. The transport unit 7 then drives the multijoint robot 71 to position and set the wafer WF on the support surface 63A of the inner table 63 based on a detection result of the detector 5. Specifically, the position of a center CP of the wafer WF coincides with that of a center of the support surface 63A, and a center of the notch VN is situated on the right side of a straight line passing through the center of the support surface 63A in parallel with the X-axis.

The press unit 3 then drives the linear motor 25 so that the press roller 32 is moved to a position shown by chain double-dashed lines in FIG. 1 while rotating on the adhesive sheet AS, thereby pressing and sticking the adhesive sheet AS to a surface of the wafer WF. Subsequently, the cutter 8 drives the multijoint robot 71 to replace the suction tool 72 with the cutter tool 82 and move the cutter blade 81 along the outer periphery of the wafer WF. The adhesive sheet AS is thus cut along the outer periphery of the wafer WF.

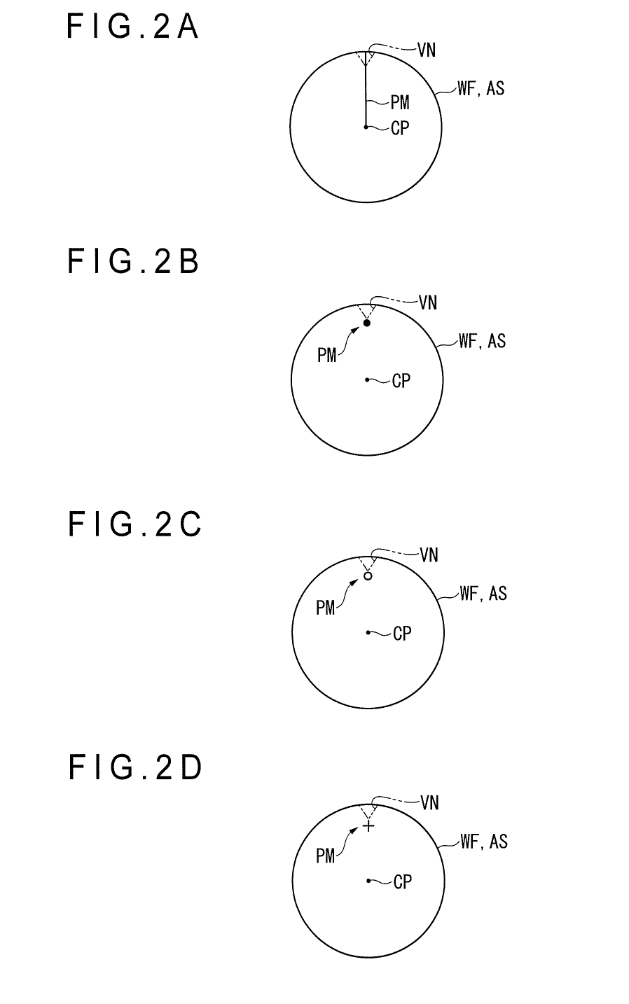

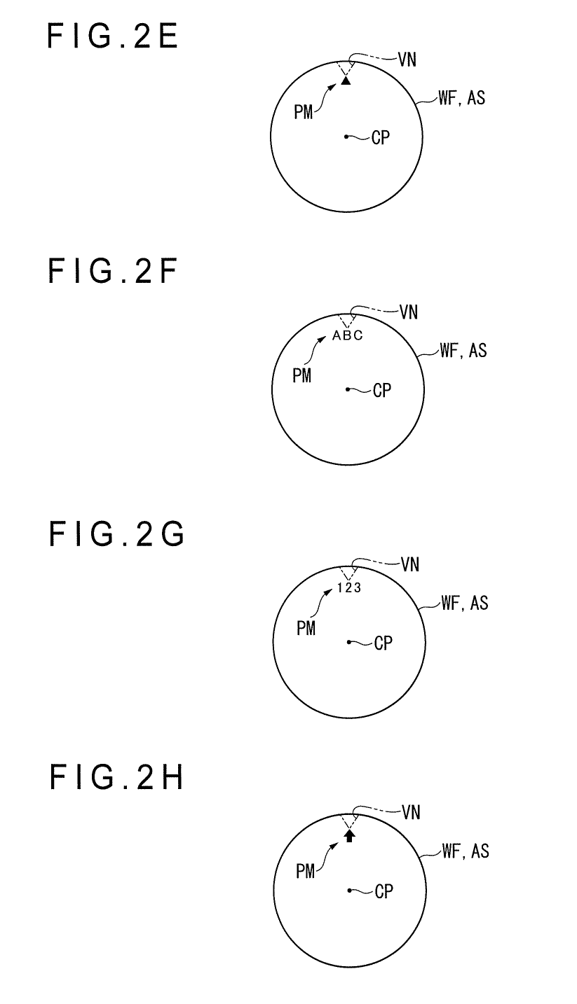

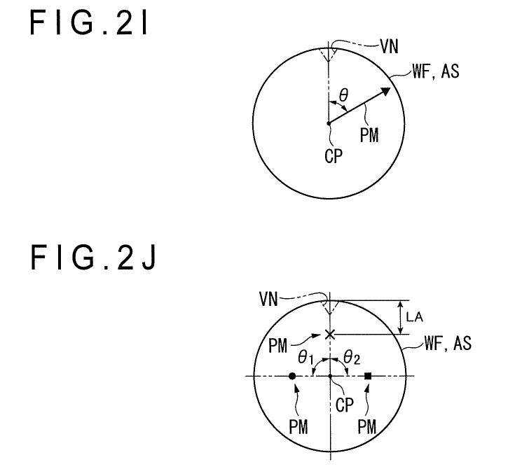

The mark-providing unit 4 then drives the linear motor 25 and the printer 42 so that the printer 42 is moved leftward as shown by right chain double-dashed lines in FIG. 1 to provide the position recognition mark PM in the form of a straight line parallel with the X-axis to the cut adhesive sheet AS at a predetermined position. In the exemplary embodiment, as shown in FIG. 2A, the mark-providing unit 4 prints the straight line passing through the center CP of the wafer WF and the center of the notch VN so that the straight line has a predetermined positional pattern relative to the notch VN. The transport unit 7 then drives the multijoint robot 71 to replace the cutter tool 82 with the suction tool 72. Subsequently, the transport unit 7 drives the decompressor (not shown) to hold the wafer WF stuck with the adhesive sheet AS by suction with the suction tool 72, and transports it to a downstream apparatus for a downstream process. The position recognition mark PM has the predetermined positional pattern relative to the notch VN. Therefore, as long as the pattern is stored in the downstream apparatus for the downstream process in advance, the downstream apparatus can indirectly detect the position of the notch VN by detecting the position recognition mark PM even when failing to detect the notch VN. The wafer WF can thus be positioned to be subjected to a predetermined process.

Subsequently, the mark-providing unit 4 drives the linear motors 25, 41 to move the printer 42 close to the press roller 32 shown by left chain double-dashed lines in FIG. 1 and then move it upward. The press unit 3 drives the linear motor 31 to move the press roller 32 upward. The feeder 2 then drives the rotary motor 26A and the linear motor 25 to move the drive roller 26 to a position shown by chain double-dashed lines in FIG. 1 while rotating, thereby separating the unnecessary sheet US from the upper surface 61A of the outer table 61. The feeder 2 then drives the linear motor 25 and the rotary motors 23A, 29A to move the slider 25A rightward while the rotation of the drive roller 26 is stopped, thereby feeding an unused part of the adhesive sheet AS while winding the unnecessary sheet US onto the recycling roller 29. The press unit 3 and the mark-providing unit 4 then drive the linear motors 25, 31, 41 to move the press roller 32 and the printer 42 to positions shown by solid lines in FIG. 1, and the above operation is repeated.

In the exemplary embodiment, the predetermined position recognition mark PM, which has the predetermined positional pattern relative to the notch VN, is provided to the adhesive sheet AS at the predetermined position within the area stuck to the wafer WF. The adhesive sheet AS can thus be stuck to the wafer WF in a manner that a downstream apparatus can recognize the notch VN of the wafer WF.

Incidentally, although the best arrangements, methods and the like for carrying out the invention are disclosed above, the invention is not limited thereto.

In other words, while the invention has been particularly explained and illustrated mainly in relation to a specific embodiment, a person skilled in the art could make various modifications in terms of shape, material, quantity or other particulars to the above described embodiment without deviating from the technical idea or any object of the invention. Accordingly, any descriptions of shape, material and the like disclosed above are given as examples to enable easy understanding of the invention, and do not limit the invention, so that descriptions using names of components, with any such limitations of shape, material and the like removed in part or whole, are included in the invention.

For instance, the mark-providing unit 4 may set the printer 42 immediately at the right of the feed-side frame 2A as shown in chain double-dashed lines in FIG. 1 to provide the position recognition mark PM to at least one of the base sheet BS and the adhesive layer AD before the adhesive sheet AS is stuck to the wafer WF.

The printer 42 may be any one of an inkjet printer, a thermal printer, a relief printing machine, an intaglio printing machine, a laser printer and the like, or any combination thereof as long as the position recognition mark PM can be printed on the adhesive sheet AS.

The mark-providing unit 4 may provide the position recognition mark PM to a side surface of the adhesive sheet AS, and the position recognition mark PM may be in the same shape as the notch VN detected by the detector 5.

The mark-providing unit 4 may use laser beam, ultrasonic or the like in place of or in combination with the printer 42 to provide the position recognition mark PM to a surface or an inside of the base sheet BS, a surface or an inside of adhesive layer AD, or a boundary between the base sheet BS and the adhesive layer AD. When the mark-providing unit 4 uses laser, ultrasonic or the like, the base sheet BS or the adhesive layer AD may be modified, altered, melt, burnt or colored at a focal point of the outputted energy to cause a chemical reaction of a component of the adhesive sheet AS, thereby providing the position recognition mark PM. The above technique, unlike a printing technique, can prevent the position recognition mark PM from being abraded or made to disappear by water and chemicals used for a variety of treatments performed by other apparatuses and/or contact with another article.

Further, the inner table 63 of the support unit 6 may be not only rotatable, but also movable in both of the X- and Y-axis directions so that, after the adhesive sheet AS is cut by the cutter 8, the detector 5 detects the outer periphery and the notch VN of the wafer WF, the support unit 6 moves the wafer WF to a predetermined position, and the mark-providing unit 4 provides the position recognition mark PM.

The mark-providing unit 4 may provide the position recognition mark PM before the adhesive sheet AS is cut by the cutter 8.

Further, the mark-providing unit 4 may include the multijoint robot 71 and the printer 42 so that the mark-providing unit 4 drives the multijoint robot 71 relative to the wafer WF set on the inner table 63 at a predetermined position (orientation) to provide the position recognition mark PM based on the detection result of the detector 5 in the same manner as described above.

The position recognition mark PM is by no means limited and may be in any shape such as point, circle (e.g., perfect circle and oval), cross, polygon, letter, digit and diagram as shown in FIGS. 2B to 2H. Further, as shown in FIG. 21, the position recognition mark PM may be provided at a position shifted from the position of the notch VN by a predetermined angle θ. Alternatively, as shown in FIG. 2J, a plurality of position recognition marks PM may be provided at positions not close to an outer edge of the adhesive sheet AS but spaced from the outer edge by a predetermined distance LA, and shifted around the center CP of the wafer WF from the position of the notch VN by predetermined angles θ1 and θ2 (it is not essential that θ1, θ2 each be 90 degrees). The position recognition mark PM is only required to be provided to the adhesive sheet AS with the predetermined positional pattern relative to the notch VN.

The feeder 2 may separate an adhesive sheet from a raw sheet where a plurality of adhesive sheets in a predetermined shape are temporarily attached to a release sheet and feed the separated adhesive sheet, or may alternatively feed a single adhesive sheet not temporarily attached to a release sheet.

The press unit 3 may include a blade-shaped pressing member, or a pressing member of rubber, resin, sponge or the like in place of the press roller 32, or may alternatively press the adhesive sheet by air ejection.

The cutter 8 is not limited as long as the cutter 8 can cut the adhesive sheet AS. For instance, the adhesive sheet may be cut with a laser cutter or by water pressure or wind pressure. Further, a cutter blade such as a rotary cutter that is rotated to cut is also available. The cutter 8 may be independent of the transport unit 7. Further, the cutter 8 may cut the adhesive sheet AS into a V-shape along the notch VN.

According to the invention, the adhesive sheet AS and the adherend are not particularly limited in terms of material, type, shape and the like. For instance, the adhesive sheet AS may be a pressure-sensitive adhesive sheet, a heat-sensitive adhesive sheet or the like. For instance, when the adhesive sheet AS is a heat-sensitive adhesive sheet, an appropriate heater may be provided to heat the adhesive sheet AS. For instance, the adhesive sheet AS may include only a single adhesive layer AD, or may include three or more layers such as the base sheet BS, the adhesive layer AD and an intermediate layer therebetween, the base sheet BS being optionally provided with a cover layer on an upper surface thereof. Alternatively, the adhesive sheet AS may be a so-called double-sided adhesive sheet including the base sheet BS separable from the adhesive layer AD, and the double-sided adhesive sheet may include a single or a plurality of intermediate layers, or may include a single or a plurality of layers not including an intermediate layer. For instance, the adherend may be a member or article in any form such as food, resin container, semiconductor wafer (e.g., a silicon semiconductor wafer and a compound semiconductor wafer), circuit board, information recording media (e.g., an optical disc), glass plate, steel plate, pottery, wooden plate and resin plate. It should be noted that the adhesive sheet AS may be named after a function or an intended use thereof. For instance, the adhesive sheet AS may be provided in the form of a sheet, film, tape or the like in a predetermined shape (e.g., an information recording label, a decoration label, a protection sheet, a dicing tape, a die-attach film, die-bonding tape, and a resin sheet for forming a recording layer) attachable to adherends such as the above.

When the adherend is the wafer WF, the reference portion may be a bearing mark such as an orientation flat, a serial number stamped on the wafer WF, a circuit pattern, a kerf or a street. Even when the adherend is not the wafer WF, the reference potion is not particularly limited as long as the reference position has a predetermined pattern and functions as a mark helping the recognition of the position of the adherend.

The invention is by no means limited to the above units and processes as long as the above operations, functions or processes of the units and processes are achievable, still less to the above merely exemplary arrangements and processes described in the exemplary embodiment. For instance, the mark-providing unit is by no means limited as long as the mark-providing unit can provide a predetermined position recognition mark, which has a predetermined positional pattern relative to a reference position, to an adhesive sheet within an area stuck to an adherend and falls within a relevant technical range in view of common techniques at the time of the filing of this application (description of the other units and processes are omitted).

The drivers of the exemplary embodiment may each be any one of electric devices such as a rotary motor, a direct-acting motor, a linear motor, a monoaxial robot and a multijoint robot, and actuators such as an air cylinder, a hydraulic cylinder, a rodless cylinder and a rotary cylinder, and direct or indirect combinations thereof (including the examples described in exemplary embodiment).

### EXPLANATION OF CODE(S)

1 sheet sticking apparatus

2 feeder

3 press unit

4 mark-providing unit

AS adhesive sheet

PM position recognition mark

VN notch (reference portion)

WF wafer (adherend)

1. A sheet sticking apparatus comprising:
a feeder configured to feed an adhesive sheet;
a press unit configured to press and stick the adhesive sheet to an adherend provided with a reference portion at a predetermined position; and
a mark-providing unit configured to provide a predetermined position recognition mark to the adhesive sheet at a predetermined position within an area stuck to the adherend, the position recognition mark having a predetermined positional pattern relative to the reference portion.

2. The sheet sticking apparatus according to claim 1, wherein the mark-providing unit causes a chemical reaction of a component of the adhesive sheet to provide the position recognition mark.

3. A sheet sticking method comprising:
feeding an adhesive sheet;
pressing and sticking the adhesive sheet to an adherend provided with a reference portion at a predetermined position; and
providing a predetermined position recognition mark to the adhesive sheet at a predetermined position within an area stuck to the adherend, the position recognition mark having a predetermined positional pattern relative to the reference portion.
